(19) United States
(12) Patent Application Publication
(10) Pub. No.: US 2025/0338718 A1
(43) Pub. Date: Oct. 30, 2025

(54) DISPLAY DEVICE, ELECTRONIC DEVICE, AND MANUFACTURING METHOD OF DISPLAY DEVICE

(71) Applicant: Samsung Display Co., Ltd., Yongin-si (KR)

(72) Inventor: EOK SU KIM, Yongin-si (KR)

(21) Appl. No.: 19/043,274

(22) Filed: Jan. 31, 2025

(30) Foreign Application Priority Data
Apr. 26, 2024 (KR) 10-2024-0055850

(51) Int. Cl. H10K 59/121; H10K 59/12; H10K 59/124; H10K 59/131

(52) U.S. Cl. CPC H10K 59/1213; H10K 59/1201; H10K 59/124; H10K 59/1315

(57) ABSTRACT

A display device includes a base substrate, a transistor including a gate electrode and a semiconductor pattern, the semiconductor pattern including a source region, an active region, and a drain region and located on the base substrate, a gate insulating pattern layer on the semiconductor pattern, and a connection electrode electrically connected to the semiconductor pattern and being on the gate insulating pattern layer, wherein the gate electrode and the connection electrode are at a same layer, each of the gate electrode and the connection electrode includes a first conductive layer and a second conductive layer on the first conductive layer, and no through hole is defined in the semiconductor pattern.

### CROSS-REFERENCE TO RELATED APPLICATION

The present application claims priority to and the benefit of Korean Patent Application No. 10-2024-0055850, filed on Apr. 26, 2024, in the Korean Intellectual Property Office, the entire disclosure of which is incorporated by reference herein.

### BACKGROUND

The present disclosure herein relates to a display device and a manufacturing method thereof, and more particularly, to a display device including a gate electrode and a connection electrode and a manufacturing method thereof.

Multimedia electronic devices such as televisions, mobile phones, tablet PCs, computers, navigation devices, and game consoles may include a display panel for displaying an image. The display panel may include a plurality of pixels for displaying an image, and the pixels may each include a light-emitting element that generates light and a driving element connected to the light-emitting element.

The light-emitting element and the driving element of the display panel may be formed through stacking a thin film and patterning the thin film using a mask. Because a manufacturing process for a display panel using a mask is expensive, it may be necessary to simplify a manufacturing process for a display panel to reduce the number of masks required for manufacturing a display device. Also, it may be required to manufacture a display panel having reliability while a manufacturing process is simplified.

### SUMMARY

The present disclosure provides a display device having improved reliability by improving current flow and contact resistance.

The present disclosure also provides a manufacturing method of a display device having improved processability and reliability.

One or more embodiments of the present disclosure provide a display device including a base substrate, a transistor including a gate electrode and a semiconductor pattern, the semiconductor pattern including a source region, an active region, and a drain region and located on the base substrate, a gate insulating pattern layer on the semiconductor pattern, and a connection electrode electrically connected to the semiconductor pattern and being on the gate insulating pattern layer, wherein the gate electrode and the connection electrode are at a same layer, each of the gate electrode and the connection electrode includes a first conductive layer and a second conductive layer on the first conductive layer, and no through hole is defined in the semiconductor pattern.

In one or more embodiments, the gate electrode and the connection electrode may include a same material.

In one or more embodiments, a thickness of the first conductive layer may be smaller than a thickness of the second conductive layer.

In one or more embodiments, the first conductive layer may include a material that is not etched by an etching solution for etching the second conductive layer.

In one or more embodiments, the first conductive layer may include titanium (Ti), molybdenum (Mo), or an alloy thereof, and the second conductive layer may include copper (Cu).

In one or more embodiments, the connection electrode may be electrically connected to the drain region or the source region.

In one or more embodiments, the connection electrode may include a first connection electrode directly in contact with and electrically connected to the drain region, and a second connection electrode directly in contact with and electrically connected to the source region.

In one or more embodiments, the display device may further include a first conductive pattern and a second conductive pattern between the base substrate and the transistor, wherein the first conductive pattern may be electrically connected to the drain region through the first connection electrode, and the second conductive pattern may be electrically connected to the source region through the second connection electrode.

In one or more embodiments, the display device may further include a light-emitting element including a first electrode on the connection electrode, an emission layer on the first electrode, and a second electrode on the emission layer, wherein the first electrode may be electrically connected to the transistor through the connection electrode.

In one or more embodiments of the present disclosure, an electronic device includes a display module, a window on the display module, and a housing under the display module, the display module includes a base substrate, a transistor including a gate electrode and a semiconductor pattern, the semiconductor pattern including a source region, an active region, and a drain region and located on the base substrate, a gate insulating pattern layer on the semiconductor pattern, and a connection electrode electrically connected to the semiconductor pattern and being on the gate insulating pattern layer, wherein the gate electrode and the connection electrode are at a same layer, each of the gate electrode and the connection electrode includes a first conductive layer including first metal, and a second conductive layer including second metal different from the first metal and located on the first conductive layer, and the second metal is not etched by an etching solution that etches the first metal.

In one or more embodiments, the first conductive layer may include titanium (Ti), molybdenum (Mo), or an alloy thereof, and the second conductive layer may include copper (Cu).

In one or more embodiments, a thickness of the first conductive layer may be smaller than a thickness of the second conductive layer.

In one or more embodiments, the gate electrode and the connection electrode may include a same material.

In one or more embodiments, no through hole may be defined in the semiconductor pattern.

In one or more embodiments, the connection electrode may be electrically connected to the drain region or the source region.

In one or more embodiments, the connection electrode may include a first connection electrode directly in contact with and electrically connected to the drain region, and a second connection electrode directly in contact with and electrically connected to the source region.

In one or more embodiments, the display device may further include a first conductive pattern and a second conductive pattern between the base substrate and the transistor, wherein the first conductive pattern may be electrically connected to the drain region through the first connection electrode, and the second conductive pattern may be electrically connected to the source region through the second connection electrode.

In one or more embodiments, the display device may further include a light-emitting element including a first electrode on the connection electrode, an emission layer on the first electrode, and a second electrode on the emission layer, wherein the first electrode may be electrically connected to the transistor through the connection electrode.

In one or more embodiments of the present disclosure, a manufacturing method of a display device includes providing a preliminary display panel including a base substrate, a preliminary semiconductor pattern on the base substrate, and a gate insulating pattern layer having an insulating layer opening exposing a portion of the preliminary semiconductor pattern, the gate insulating pattern layer being on the preliminary semiconductor pattern, forming a semiconductor pattern by doping a portion of the preliminary semiconductor pattern exposed by the insulating layer opening, and forming a gate electrode and a connection electrode on the gate insulating pattern layer, wherein the forming of the gate electrode and the connection electrode includes forming a first conductive layer on the gate insulating pattern layer and forming a second conductive layer on the first conductive layer, patterning the second conductive layer through wet etching, and patterning the first conductive layer through dry etching.

In one or more embodiments, in the patterning of the second conductive layer through wet etching, the semiconductor pattern may be covered with the first conductive layer and prevented from being damaged.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles and scope of the present disclosure. In the drawings:

FIG. 1A is an assembled perspective view of a display device according to one or more embodiments of the present disclosure;

FIG. 1B is an exploded perspective view of a display device according to one or more embodiments of the present disclosure;

FIG. 2 is a cross-sectional view of a display module according to one or more embodiments of the present disclosure;

FIG. 3 is a plan view of a display panel according to one or more embodiments of the present disclosure;

FIG. 4 is a cross-sectional view taken along the line I-I′ of FIG. 3 according to one or more embodiments of the present disclosure;

FIG. 5 is a plan view corresponding to a circuit layer of FIG. 4 according to one or more embodiments of the present disclosure;

FIG. 6 is an enlarged plan view of a region AA′ of FIG. 5 according to one or more embodiments of the present disclosure;

FIG. 7 is a cross-sectional view taken along the line II-II′ of FIG. 6 according to one or more embodiments of the present disclosure; and

FIGS. 8-16 are cross-sectional views each illustrating a step of a manufacturing method of a display device according to one or more embodiments of the present disclosure.

### DETAILED DESCRIPTION

Embodiments of the present disclosure may be variously modified and have various forms, but specific embodiments will be illustrated in the drawings and described in detail in the description. However, this is not intended to limit the present disclosure to a specific form, and it should be understood that all changes, equivalents, and alternatives included in the spirit and scope of the present disclosure are included.

In this specification, the singular forms include the plural forms as well unless the context clearly indicates otherwise.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

In this specification, it will be understood that when an element (or a region, a layer, a portion, or the like) is referred to as being “on”, “connected to” or “coupled to” another element, it may be directly disposed on, connected or coupled to the other element, or an intervening element may be disposed therebetween.

Terms such as “below”, “on lower side”, “above”, and “on upper side” may be used herein to describe the relationships of the elements illustrated in the drawings. These terms have relative concepts and are described on the basis of the directions indicated in the drawings.

As used herein, the wording “disposed on” may not only mean being disposed on an upper portion of any one member but may also mean being disposed on a lower portion thereof.

As used herein, the wording “directly disposed” may mean that there is no layer, film, region, plate, etc. added between a portion such as a layer, film, region, or plate and another portion. For example, “directly disposed” may mean placing two layers or two members without using an additional member such as an adhesive member therebetween.

As used herein, the term “and/or” includes all of one or more combinations which may be defined by related elements.

Although the terms first, second, etc. may be used herein to describe various elements, these elements should not be limited by these terms. These terms are only used to distinguish one element from another element. For example, a first element may be referred to as a second element, and similarly, a second element may also be referred to as a first element without departing from the spirit and scope of the present disclosure.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Like reference numerals or symbols refer to like elements. Also, in the drawings, the thicknesses, ratios, and dimensions of the elements are exaggerated for effective description of the technical contents.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, a display device according to one or more embodiments of the present disclosure and a manufacturing method thereof will be described with reference to the drawings.

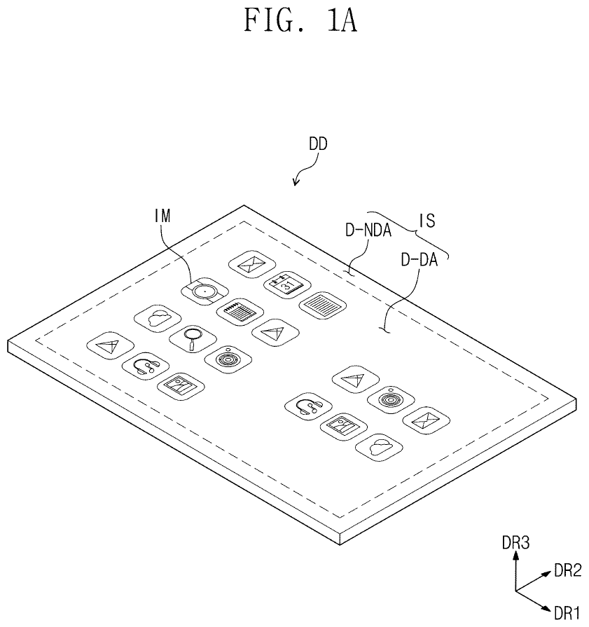

FIG. 1A is an assembled perspective view of a display device according to one or more embodiments of the present disclosure.

Referring to FIG. 1A, a display device DD may be activated in response to an electrical signal and display an image. The display device DD may be included various electronic devices that provide an image IM to a user. The electronic device may be a small- and medium-sized electronic device such as a monitor, a mobile phone, a tablet PC, a navigation device, and a game console as well as a large-sized electronic device such as a television and/or an outdoor billboard. The embodiments of the electronic device described above are examples, and thus the electronic device is not limited to any one embodiment as long as the electronic device does not depart from the spirit and scope of the present disclosure.

The display device DD may have a rectangular shape having long sides extending in a first direction DR1 and short sides extending in a second direction DR2 in a plan view. However, the present disclosure is not limited thereto, and the display device DD may have various shapes such as a circular shape and a polygonal shape.

The display device DD may display the image IM in a third direction DR3 (e.g., a thickness direction) through a display surface IS parallel to a plane defined by the first direction DR1 and the second direction DR2. The third direction DR3 may be substantially parallel to a normal direction of the display surface IS. The display surface IS on which the image IM is displayed may correspond to a front surface of the display device DD. The image IM may include a static image as well as a dynamic image. FIG. 1A illustrates icon images as an example of the image IM.

A front surface (or an upper surface) and a rear surface (or a lower surface) of each of members constituting the display device DD may be defined on the basis of the third direction DR3. A front surface and a rear surface may be opposed to each other in the third direction DR3, and a normal direction of each of a front surface and a rear surface may be parallel to the third direction DR3. A distance between a front surface and a rear surface defined along the third direction DR3 may correspond to a thickness of a member.

As used herein, the wording “in a plan view” may be defined as a state of being viewed in the third direction DR3. As used herein, the wording “in a cross-sectional view” may be defined as a state of being viewed in the first direction DR1 or the second direction DR2. However, directions indicated by the first to third directions DR1, DR2, and DR3 may have relative concepts, and may thus be changed into other directions.

FIG. 1A illustrates, as an example, the display device DD having a flat display surface IS. However, a shape of the display surface IS of the display device DD is not limited thereto, and the display surface IS may have a curved or three-dimensional shape.

The display device DD may be flexible. The term “flexible” may imply bendable characteristic, and the display device DD may be a device including any one from among a structure which is completely foldable to a structure which is bendable to a level of several nanometers. For example, the flexible display device DD may include a curved device or a foldable device. However, the present disclosure is not limited thereto, and the display device DD may be rigid.

The display surface IS of the display device DD may include a display part D-DA and a non-display part D-NDA. The display part D-DA may be a part on which the image IM is displayed within the front surface of the display device DD, and a user may view the image IM through the display part D-DA. The display part D-DA having a quadrangular shape in a plan view is illustrated as an example in this embodiment, but the display part D-DA may have various shapes according to a design of the display device DD.

The non-display part D-NDA may be a part on which the image IM is not displayed within the front surface of the display device DD. The non-display part D-NDA may be a part that has a suitable color (e.g., a predetermined color) and blocks light. The non-display part D-NDA may be adjacent to the display part D-DA. For example, the non-display part D-NDA may be disposed outside the display part D-DA and surround the display part D-DA along an edge or a periphery of the display part D-DA. However, this is illustrated as an example, and the non-display part D-NDA may be adjacent to only one side of the display part D-DA or disposed on a side surface, not the front surface, of the display device DD, or the non-display part D-NDA may be omitted.

The display device DD according to one or more embodiments may sense an external input applied from the outside. The external input may have various forms such as light, temperature, and pressure provided from the outside. The external input may include not only an input (for example, a contact by a user's hand or a pen) in contact with the display device DD but also an input (for example, hovering) applied close to the display device DD.

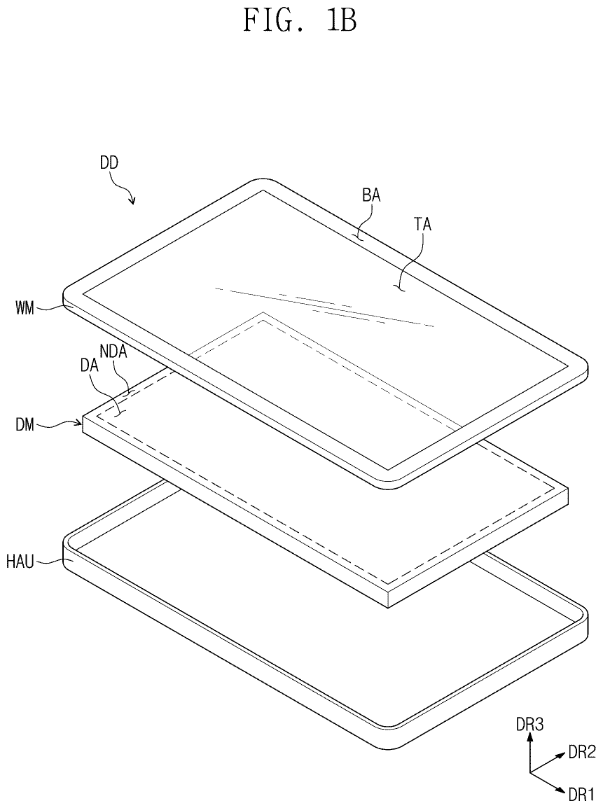

FIG. 1B is an exploded perspective view of a display device according to one or more embodiments of the present disclosure. FIG. 2 is a cross-sectional view of a display module according to one or more embodiments of the present disclosure.

Referring to FIGS. 1B and 2, the display device DD may include a window WM, a display module DM, and a housing HAU. The display module DM may include a display panel DP and a light control member.

The window WM and the housing HAU may be coupled to each other to form an exterior of the display device DD and provide an inner space capable of accommodating components of the display device DD such as the display module DM.

The window WM may be disposed on the display module DM. The window WM may protect the display module DM from an external impact. A front surface of the window WM may correspond to the display surface IS (see FIG. 1A) of the display device DD described above. The front surface of the window WM may include a transmission region TA and a bezel region BA.

The transmission region TA of the window WM may be an optically transparent region. The window WM may transmit an image provided by the display module DM through the transmission region TA, and a user may view the image. The transmission region TA may correspond to the display part D-DA (see FIG. 1A) of the display device DD described above.

The window WM may include an optically transparent insulating material. For example, the window WM may include glass, sapphire, and/or plastic. The window WM may have a single-layered or multi-layered structure. The window WM may further include a functional layer such as an anti-fingerprint layer, a phase control layer, and/or a hard coating layer disposed on an optically transparent substrate.

The bezel region BA of the window WM may be provided as a region in which a material having a suitable color (e.g., a predetermined color) is deposited, applied, and/or printed on a transparent substrate. The bezel region BA of the window WM may prevent a component of the display module DM disposed to overlap the bezel region BA from being viewed from the outside. The bezel region BA may correspond to the non-display part D-NDA (see FIG. 1A) of the display device DD described above.

The display module DM may be disposed between the window WM and the housing HAU. The display module DM may display an image in response to an electrical signal. The display module DM may include a display region DA and a non-display region NDA adjacent to the display region DA and around the display region DA along an edge or a periphery of the display region DA.

The display region DA may be a region which is activated in response to an electrical signal and in which an image is outputted. The display region DA of the display module DM may overlap the transmission region TA of the window WM. As used herein, the wording “a region/portion and a region/portion overlap each other” is not limited to a case in which regions/portions have the same area size and/or the same shape. The image outputted from the display region DA may be viewed from the outside through the transmission region TA.

The non-display region NDA may be adjacent to the display region DA. For example, the non-display region NDA may surround the display region DA. However, the present disclosure is not limited thereto, and the non-display region NDA may be defined in various shapes. The non-display region NDA may be a region in which a driving line or a driving circuit for driving elements disposed in the display region DA, various signal lines that provide an electrical signal, and pads are disposed. The non-display region NDA of the display module DM may overlap the bezel region BA of the window WM, and components disposed in the non-display region NDA may be prevented, by the bezel region BA, from being viewed from the outside.

The display panel DP according to one or more embodiments may be an emissive display panel, but is not particularly limited thereto. For example, the display panel DP may be an organic light-emitting display panel, an inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include quantum dots, quantum rods, and/or the like. Hereinafter, the display panel DP will be described as an organic light-emitting display panel.

The display panel DP may include a base substrate BS, a circuit layer DP-CL, a display element layer DP-OL, and an encapsulation layer TFE.

The base substrate BS may provide a base surface on which the circuit layer DP-CL is disposed. The base substrate BS may be a rigid substrate, but is not limited thereto, and may be a flexible substrate.

The circuit layer DP-CL may be disposed on the base substrate BS. The circuit layer DP-CL may include driving elements such as a transistor, signal lines, and signal pads. The display element layer DP-OL may include light-emitting elements disposed to overlap the display region DA. The light-emitting elements of the display element layer DP-OL may be electrically connected to the driving elements of the circuit layer DP-CL and output light through the display region DA in response to a signal from the driving elements.

The encapsulation layer TFE may be disposed on the display element layer DP-OL and encapsulate light-emitting elements. The encapsulation layer TFE may include a plurality of thin films. The thin films of the encapsulation layer TFE may be disposed to improve optical efficiency of the light-emitting elements or to protect the light-emitting elements.

A sensor layer ISU may be disposed on the display panel DP. The sensor layer ISU may sense an external input applied from the outside. The external input may be a user's input. The user's input may include external inputs in various forms such as a part of a user's body, light, heat, a pen, and/or pressure.

The sensor layer ISU may be disposed on the display panel DP through a continuous process. The sensor layer ISU may be directly disposed on the display panel DP. Being directly disposed may mean that a third component is not disposed between the sensor layer ISU and the display panel DP. That is, a separate adhesive member may not be disposed between the sensor layer ISU and the display panel DP.

Alternatively, the sensor layer ISU and the display panel DP may be coupled to each other through an adhesive member. The adhesive member may include a typical adhesive agent and/or a bonding agent.

On the other hand, the display module DM may not include the sensor layer ISU.

The display module DM may further include a light control member disposed on the display panel DP. The light control member may be provided on the display panel DP and then coupled to the display panel DP through a bonding process using a sealing member. However, the present disclosure is not limited thereto, and the light control member may be directly disposed on the display panel DP.

The light control member may convert a wavelength of light provided from the display panel DP, that is the source light, or selectively transmit the source light. For example, the light control member may include light control patterns capable of converting optical property of the source light provided from the display panel DP. The light control member may control color purity or color gamut of light outputted from the display device DD and prevent reflection of external light incident from outside the display device DD.

The light control member may include a base layer, a color filter layer, and a light control layer. The base layer may be disposed to face the base substrate BS of the display panel DP, and the color filter layer and the light control layer disposed on the base layer may be placed between the display panel DP and the base layer.

The light control layer may include a quantum dot (e.g., quantum dots) that converts a wavelength of source light provided from the display panel DP or further include a transmission part that transmits the source light. The source light passed through the quantum dot included in the light control layer may be outputted as light having a different color from the source light.

The color filter layer may include color filters, and the color filters may transmit or absorb light passed through the light control layer according to a color. The color filter layer may absorb light that has failed to be converted by the light control layer, thereby preventing color purity of the display device DD from being deteriorated. In addition, the color filter layer may filter external light to the same color as pixels, thereby preventing external light reflection.

A sealing member may be disposed in the non-display region NDA, which is an outer peripheral portion of the display module DM, and prevent foreign substances, oxygen, moisture, and/or the like from being introduced into the display module DM from outside the display module DM. The sealing member may be formed from sealant including a curable resin.

The display module DM according to one or more embodiments may further include a filling layer disposed between the display panel DP and a light control member. The filling layer may fill a space between the display panel DP and the light control member. The filling layer may function as a buffer between the display panel DP and the light control member. In one or more embodiments, the filling layer may absorb an impact and increase rigidity of the display module DM.

The filling layer may be formed from a filling resin including a polymer resin. For example, the filling layer may include an acrylic resin, an epoxy-based resin, and/or the like. However, a light control member according to one or more embodiments may be directly disposed on the display panel DP, and thus a filling layer and a sealing member may be omitted. In one or more embodiments in which a light control member is directly disposed on the display panel DP, a base layer of the light control member may be omitted.

The housing HAU may be disposed under the display module DM and accommodate the display module DM. The housing HAU may protect the display module DM by absorbing an impact applied to the display module DM from the outside and preventing foreign substances and/or moisture, etc. from infiltrating to the display module DM. The housing HAU according to one or more embodiments may be provided in a form in which a plurality of accommodation members are coupled.

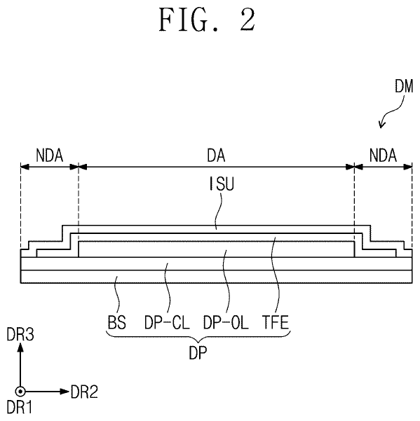

FIG. 3 is a plan view of a display panel according to one or more embodiments of the present disclosure.

Referring to FIG. 3, the display panel DP may include pixels PX11 to PXnm disposed in the display region DA and signal lines SL1 to SLn and DL1 to DLm electrically connected to the pixels PX11 to PXnm. The display panel DP may include pads PD and a driving circuit GDC disposed in the non-display region NDA.

The pixels PX11 to PXnm may each include a light-emitting element and a pixel driving circuit configured with a plurality of transistors (for example, a switching transistor, a driving transistor, etc.) connected to the light-emitting element and a capacitor. The pixels PX11 to PXnm may emit light in response to an electrical signal applied to the pixels PX11 to PXnm. FIG. 3 illustrates, as an example, the pixels PX11 to PXnm arranged in a matrix form (e.g., the pixels PX11 to PXnm may be arranged along rows and columns of a matrix), but an arrangement form of the pixels PX11 to PXnm is not limited thereto.

The signal lines SL1 to SLn and DL1 to DLm may include scan lines SL1 to SLn and data lines DL1 to DLm. Each of the pixels PX11 to PXnm may be connected to a corresponding scan line from among the scan lines SL1 to SLn and a corresponding data line from among the data lines DL1 to DLm. More various signal lines may be included in the display panel DP according to a configuration of the pixel driving circuit of the pixels PX11 to PXnm.

The driving circuit GDC may include a gate driving circuit. The gate driving circuit may generate gate signals and sequentially output the gate signals to the scan lines SL1 to SLn. The gate driving circuit may further output another control signal to the pixel driving circuits of the pixels PX11 to PXnm.

The pixels PX11 to PXnm and the driving circuit GDC according to one or more embodiments may include a plurality of transistors that is formed through a low temperature polycrystalline silicon (LTPS) process, a low temperature polycrystalline oxide (LTPO) process, and/or an oxide semiconductor process.

The pads PD may be arranged in the non-display region NDA along one direction. The pads PD may be portions connected to a circuit board. Each of the pads PD may be connected to a corresponding signal line from among the signal lines SL1 to SLn and DL1 to DLm and connected to a corresponding pixel from among the pixels PX11 to PXnm through the signal line. The pads PD may have an integrated shape (e.g., may be integrally connected) with the signal lines SL1 to SLn and DL1 to DLm. However, the present disclosure is not limited thereto, and the pads PD and the signal lines SL1 to SLn and DL1 to DLm may be disposed on different layers and connected through a contact hole.

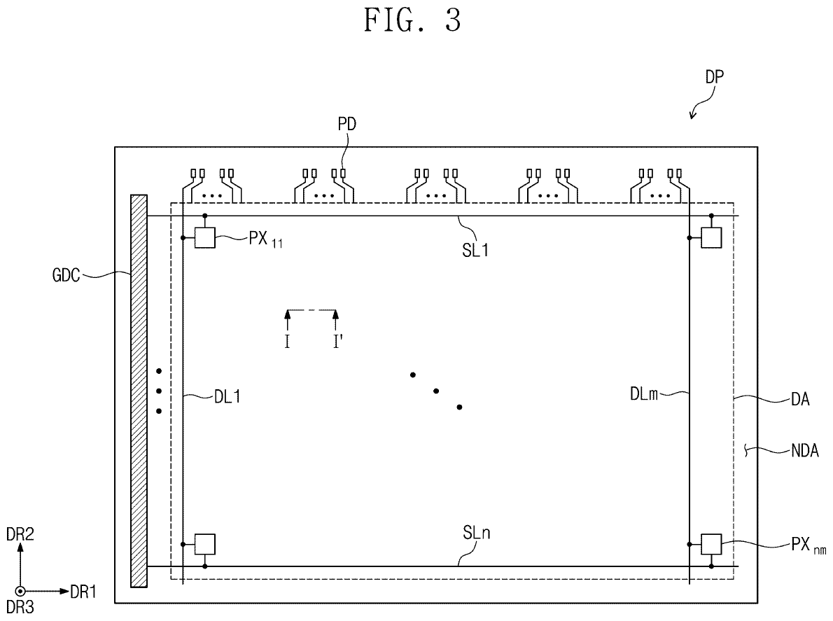

FIG. 4 is a cross-sectional view taken along the line I-I′ of FIG. 3 according to one or more embodiments of the present disclosure.

Referring to FIG. 4, the display panel DP may include the base substrate BS, the circuit layer DP-CL, the display element layer DP-OL, and the encapsulation layer TFE.

The circuit layer DP-CL may include conductive patterns CPT1 and CPT2, a transistor TR, connection electrodes CNE1 and CNE2, a buffer layer BFL, a gate insulating pattern layer GIL, and insulating layers INS1 and INS2 disposed on the base substrate BS.

A first conductive pattern CPT1 and a second conductive pattern CPT2 may be disposed between the base substrate BS and the transistor TR and disposed to be spaced (e.g., spaced apart) from each other in a plan view and/or in a cross sectional view. The first conductive pattern CPT1 may be electrically connected to a first drain portion D-A1 of a drain region D-A through a first connection electrode CNE1. The second conductive pattern CPT2 may be electrically connected to a first source portion S-A1 of a source region S-A through a second connection electrode CNE2.

The first conductive pattern CPT1 and the second conductive pattern CPT2 may each have a single-layered structure. The first conductive pattern CPT1 and the second conductive pattern CPT2 may be referred to as a pattern layer PT. The first conductive pattern CPT1 and the second conductive pattern CPT2 may be formed of the same material and may have the same stacked structure. The first conductive pattern CPT1 and the second conductive pattern CPT2 may each have a multi-layered structure. For example, the first conductive pattern CPT1 and the second conductive pattern CPT2 may each include a first pattern layer and a second pattern layer stacked on the base substrate BS in a thickness direction of the base substrate BS (e.g., the third direction DR3). However, the present disclosure is not necessarily limited thereto, and the first and second conductive patterns CPT1 and CPT2 may each have a structure in which three or more pattern layers are stacked.

The pattern layer PT may include molybdenum (Mo), aluminum (Al), chromium (Cr), gold (Au), titanium (Ti), nickel (Ni), neodymium (Nd), and/or copper (Cu), and/or an alloy including one or more thereof. However, the present disclosure is not limited thereto.

The buffer layer BFL may be disposed on the base substrate BS to cover the first and second conductive patterns CPT1 and CPT2. The buffer layer BFL may include at least one inorganic film.

The transistor TR may include a semiconductor pattern SP and a gate electrode GE. The semiconductor pattern SP may be disposed on the buffer layer BFL. A bonding force between the semiconductor pattern SP and the base substrate BS may be improved by the buffer layer BFL. The semiconductor pattern SP may include a semiconductor material such as poly silicon, crystalline silicon, and/or metal oxide.

The source region S-A, an active region A-A, and the drain region D-A of the transistor TR may be formed from the semiconductor pattern SP. The semiconductor pattern SP may have a different electrical property according to whether the semiconductor pattern SP is doped or not or whether metal oxide is reduced or not. The drain region D-A and the source region S-A, of the semiconductor pattern SP, having relatively high conductivity may serve as an electrode or a signal line. A region, which is not doped or is doped at a low concentration, or is not reduced, of the semiconductor pattern SP may correspond to the active region A-A having low conductivity. The active region A-A may be disposed between the source region S-A and the drain region D-A in a plan view and/or in a cross sectional view.

The drain region D-A may include the first drain portion D-A1 and a second drain portion D-A2. The first drain portion D-A1 may be a portion having higher conductivity than the second drain portion D-A2. The first drain portion D-A1 may be a portion having first conductivity. The second drain portion D-A2 may have second conductivity that is lower than the first conductivity. The first drain portion D-A1 may be a region doped at a higher concentration compared to the second drain portion D-A2. Accordingly, when current flows in from the active region A-A, the current may flow in mainly through the first drain portion D-A1.

The source region S-A may include the first source portion S-A1 and a second source portion S-A2. The first source portion S-A1 may be a portion having higher conductivity than the second source portion S-A2. The first source portion S-A1 may be a portion having third conductivity. The second source portion S-A2 may have fourth conductivity that is lower than the third conductivity. The first source portion S-A1 may be a region doped at a higher concentration compared to the second source portion S-A2. Accordingly, when current flows in the active region A-A, the current may flow in mainly through the first source portion S-A1.

The gate insulating pattern layer GIL may be disposed on the buffer layer BFL and a semiconductor pattern SP. The gate insulating pattern layer GIL may include at least one inorganic film. The gate insulating pattern layer GIL may include first to third insulating patterns G11, G12, and G13 that are spaced (e.g., spaced apart) from each other. An insulating layer opening OP-TR may be defined in the gate insulating pattern layer GIL. The first gate insulating pattern G11, the second gate insulating pattern G12, and the third gate insulating pattern G13 may be divided from each other by the insulating layer opening OP-TR in a cross-sectional view. The first gate insulating pattern G11, the second gate insulating pattern G12, and the third gate insulating pattern G13 are shown as being divided from each other, but may be substantially one component.

The first gate insulating pattern G11 may cover the second drain portion D-A2 of the drain region D-A and may be disposed on the first conductive pattern CPT1. The second gate insulating pattern G12 may be disposed on the active region A-A. In a plan view, the second gate insulating pattern G12 may have a shape corresponding to the active region A-A. The second gate insulating pattern G12 may cover the active region A-A. The third gate insulating pattern G13 may cover the second source portion S-A2 of the source region S-A.

The connection electrodes CNE1 and CNE2 may include a first connection electrode CNE1 and a second connection electrode CNE2. The first connection electrode CNE1 may be disposed on the first gate insulating pattern G11. The first connection electrode CNE1 may be connected to the first conductive pattern CPT1 through a first contact hole CH1 passing through the buffer layer BFL and the first gate insulating pattern G11. The first connection electrode CNE1 may be in contact with the first drain portion D-A1 of the drain region D-A and electrically connected to the drain region D-A. The first drain portion D-A1 and the first conductive pattern CPT1 may be electrically connected to each other through the first connection electrode CNE1. The first conductive pattern CPT1 and the first drain portion D-A1 having excellent conductivity may be connected to the drain region D-A, and thus current transmission characteristic may be improved.

The first connection electrode CNE1 may be directly in contact with the drain region D-A. The first connection electrode CNE1 may be directly disposed on an upper surface of the first drain portion D-A1. The first connection electrode CNE1 may be directly connected to the first drain portion D-A1, and thus resistance may be reduced when peripheral current flow moves in the third direction DR3.

The second connection electrode CNE2 may be disposed on the third gate insulating pattern G13. The second connection electrode CNE2 may be connected to the second conductive pattern CPT2 through a second contact hole CH2 passing through the buffer layer BFL and the third gate insulating pattern G13. The second connection electrode CNE2 may be in contact with the first source portion S-A1 of the source region S-A and electrically connected to the source region S-A. The source region S-A and the second conductive pattern CPT2 may be electrically connected to each other through the second connection electrode CNE2. The second connection electrode CNE2 may be connected to a power line that supplies power to a light-emitting element OL and provide a first voltage to the transistor TR.

The second connection electrode CNE2 may be directly in contact with the source region S-A. The second connection electrode CNE2 may be directly disposed on an upper surface of the first source portion S-A1. The second connection electrode CNE2 may be directly connected to the first source portion S-A1, and thus resistance may be reduced when peripheral current flow moves in the third direction DR3.

The gate electrode GE may be disposed on the second gate insulating pattern G12. The gate electrode GE may overlap the active region A-A in a plan view and/or in a cross sectional view, and may be spaced (e.g., spaced apart) from the semiconductor pattern SP with the second gate insulating pattern G12 therebetween in a thickness direction of the base substrate BS (e.g., the third direction DR3).

The connection electrodes CNE1 and CNE2 and the gate electrode GE may be spaced (e.g., spaced apart) from each other in a plan view. The connection electrodes CNE1 and CNE2 and the gate electrode GE may be disposed at the same layer and may include the same material. The connection electrodes CNE1 and CNE2 and the gate electrode GE may each have a multi-layered structure in which conductive layers ML1 and ML2 including different materials are stacked. The conductive layers ML1 and ML2 may include a first conductive layer ML1 and a second conductive layer ML2. The first and second conductive layers ML1 and ML2 may be stacked through a sputtering process, but the present disclosure is not limited thereto.

The first and second conductive layers ML1 and ML2 may each include a metal material. For example, the first and second conductive layers ML1 and ML2 may each include molybdenum (Mo), aluminum (Al), chromium (Cr), gold (Au), titanium (Ti), nickel (Ni), neodymium (Nd), copper (Cu), and/or indium tin oxide (ITO), and/or an alloy including one or more thereof. The first and second conductive layers ML1 and ML2 may include different metal materials.

The first conductive layer ML1 may include a metal material that is dry etched, and the second conductive layer ML2 may include a metal material that is wet etched. The second conductive layer ML2 may include a metal material having excellent conductivity. For example, the first conductive layer ML1 may include titanium (Ti), molybdenum (Mo), and/or an alloy including one or more thereof, and the second conductive layer ML2 may include copper (Cu). However, the present disclosure is not limited thereto, and any metal material that may be dry etched may be applied to the first conductive layer ML1, and any metal material that may be wet etched may be applied to the second conductive layer ML2.

Thicknesses of the first and second conductive layers ML1 and ML2 may be different. For example, a thickness of the second conductive layer ML2 including a material having high conductivity may be greater than a thickness of the first conductive layer ML1. Accordingly, the connection electrodes CNE1 and CNE2 and the gate electrode GE including the first and second conductive layers ML1 and ML2 may have characteristics of low resistance and high conductivity.

The connection electrodes CNE1 and CNE2 and the gate electrode GE may be concurrently (e.g., simultaneously) formed through the same process. The connection electrodes CNE1 and CNE2 and the gate electrode GE may have the same stacked structure. For example, the connection electrodes CNE1 and CNE2 and the gate electrode GE may have a Ti/Cu structure. Because the connection electrodes CNE1 and CNE2 and the gate electrode GE may be concurrently (e.g., simultaneously) formed through the same process, the display panel DP may be manufactured through a simplified process.

A first insulating layer INS1 may be disposed on the gate insulating pattern layer GIL to cover the connection electrodes CNE1 and CNE2 and the gate electrode GE. A second insulating layer (or an insulating layer) INS2 may be disposed on the first insulating layer INS1. The first insulating layer INS1 and the second insulating layer INS2 may each include an inorganic film and/or an organic film. The inorganic film may include aluminum oxide, titanium oxide, silicon oxide, silicon nitride, silicon oxynitride, zirconium oxide, and/or hafnium oxide, but is not limited to the material. The organic film may include a phenol-based polymer, an acrylic polymer, an imide-based polymer, an arylether-based polymer, an amide-based polymer, a fluorine-based polymer, a p-xylene-based polymer, a vinyl alcohol-based polymer, and/or a combination thereof, but is not limited to the material.

The display element layer DP-OL may be disposed on the circuit layer DP-CL. The display element layer DP-OL may include a pixel-defining film PDL and the light-emitting element OL. For example, the light-emitting element OL may include an organic light-emitting element, an inorganic light-emitting element, a quantum dot light-emitting element, a micro-LED light-emitting element, or a nano-LED light-emitting element. However, the present disclosure is not limited thereto, and the light-emitting element OL may include various embodiments as long as light may be generated or the amount of light may be controlled in response to an electrical signal.

The pixel-defining film PDL may be disposed on the second insulating layer INS2 of the circuit layer DP-CL. The pixel-defining film PDL may include a polymer resin. For example, the pixel-defining film PDL may include a polyacrylate-based resin or a polyimide-based resin. The pixel-defining film PDL may further include an inorganic material in addition to a polymer resin. In addition, the pixel-defining film PDL may be formed of an inorganic material. For example, the pixel-defining film PDL may include silicon nitride (SiNₓ), silicon oxide (SiOₓ), silicon oxynitride (SiOₓN_{y}), and/or the like.

In one or more embodiments, the pixel-defining film PDL may include a light absorbing material. The pixel-defining film PDL may include a black coloring agent. The black coloring agent may include black dye and/or a black pigment. The black coloring agent may include carbon black, metal such as chromium, or an oxide thereof. However, an embodiment of the pixel-defining film PDL is not limited to the example.

The light-emitting element OL may include a first electrode AE, a hole transport region HCL, an emission layer EML, an electron transport region ECL, and a second electrode CE that are sequentially stacked.

The first electrode AE may be disposed on the second insulating layer INS2 of the circuit layer DP-CL. The first electrode AE may be connected to the first connection electrode CNE1 through a contact hole CHa passing through the first insulating layer INS1 and the second insulating layer INS2. The first connection electrode CNE1 may electrically connect the first electrode AE and the transistor TR. That is, the first electrode AE may be connected to the first connection electrode CNE1, and thus the drain region D-A may be connected to the light-emitting element OL through the first connection electrode CNE1.

A light-emitting opening PX-OP that exposes at least a portion of the first electrode AE may be defined in the pixel-defining film PDL. A portion of the first electrode AE exposed by the light-emitting opening PX-OP may correspond to a light-emitting region PXA. A region in which the pixel-defining film PDL is disposed may correspond to a non-light-emitting region NPXA. The non-light-emitting region NPXA may surround the light-emitting region PXA.

The hole transport region HCL may be disposed on the first electrode AE. The hole transport region HCL may include at least one of a hole injection layer, a hole transport layer, and/or an electron blocking layer. In addition, the hole transport region HCL may include a plurality of hole transport layers.

The emission layer EML may be disposed on the hole transport region HCL. The emission layer EML may have a single-layered structure including a single material, a single-layered structure including different materials, or a multi-layered structure having a plurality of layers including a plurality of different materials. In one or more embodiments, the emission layer EML may generate blue light, which is the source light. However, the present disclosure is not limited thereto, and the display element layer DP-OL may include light-emitting elements OL including emission layers EML that emit light in different wavelength regions.

The emission layer EML may be provided in a form of a pattern disposed in a region corresponding to the light-emitting opening PX-OP. However, the present disclosure is not limited thereto, and the emission layer EML may be provided as a common layer overlapping the light-emitting region PXA and the non-light-emitting region NPXA.

The electron transport region ECL may be disposed on the emission layer EML. The electron transport region ECL may include at least one of a hole blocking layer, an electron transport layer, and/or an electron injection layer, but the present disclosure is not limited thereto.

Each of the hole transport region HCL, the emission layer EML, and the electron transport region ECL may be formed by using various methods such as a vacuum deposition method, a spin coating method, a casting method, a Langmuir-Blodgett (LB) method, an inkjet printing method, a laser printing method, and/or a laser induced thermal imaging (LITI) method.

The second electrode CE may be disposed on the electron transport region ECL. The second electrode CE may be a common electrode. That is, the second electrode CE may be provided as a common layer overlapping all of the light-emitting region PXA and the non-light-emitting region NPXA.

The encapsulation layer TFE may cover the light-emitting element OL. The encapsulation layer TFE may encapsulate the display element layer DP-OL. The encapsulation layer TFE may include at least one insulating film. The encapsulation layer TFE according to one or more embodiments may include at least one inorganic film (hereinafter, an inorganic encapsulation film). The encapsulation layer TFE according to one or more embodiments may include inorganic encapsulation films and at least one organic film (hereinafter, an organic encapsulation film) disposed between the inorganic encapsulation films.

The inorganic encapsulation film may protect the display element layer DP-OL from moisture and/or oxygen, and the organic encapsulation film may protect the display element layer DP-OL from foreign substances such as dust particles. The inorganic encapsulation film may include silicon nitride, silicon oxynitride, silicon oxide, titanium oxide, aluminum oxide, and/or the like, but is not particularly limited thereto. The organic encapsulation film may include an acrylic compound, an epoxy-based compound, etc. The organic encapsulation film may include a photopolymerizable organic material and is not particularly limited thereto.

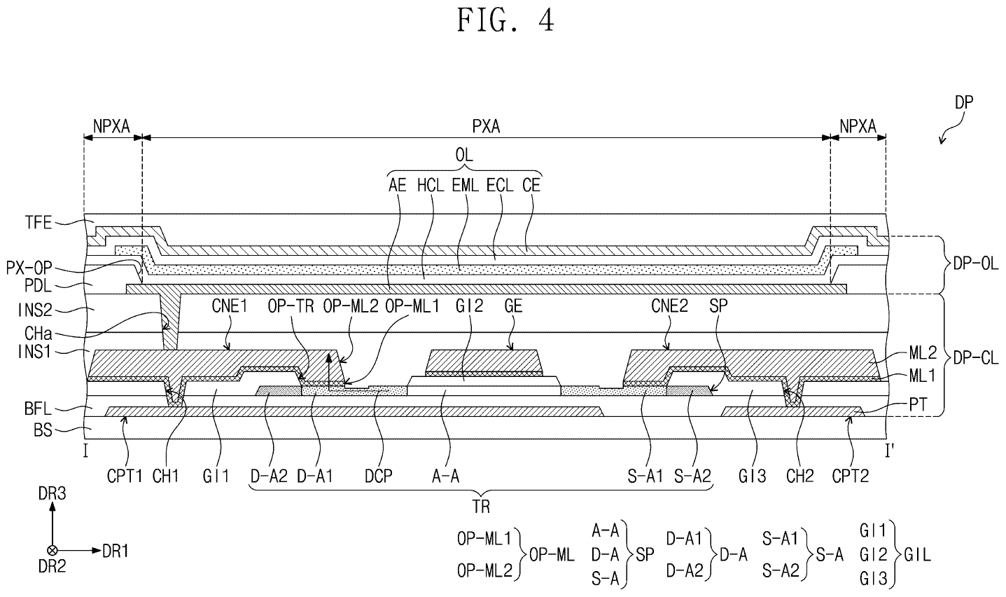

FIG. 5 is a plan view corresponding to the circuit layer of FIG. 4 according to one or more embodiments of the present disclosure. FIG. 5 illustrates a plan view of the first conductive pattern CPT1, the second conductive pattern CPT2, the semiconductor pattern SP, the gate electrode GE, the first connection electrode CNE1, and the second connection electrode CNE2.

Referring to FIG. 5, the first conductive pattern CPT1 and the second conductive pattern CPT2 may be disposed to be spaced (e.g., spaced apart) from each other in a plan view. The first connection electrode CNE1 and the second connection electrode CNE2 may be disposed to be spaced (e.g., spaced apart) from each other in a plan view. The first connection electrode CNE1 and the second connection electrode CNE2 may be disposed on the gate insulating pattern layer GIL (see FIG. 4). The first connection electrode CNE1 may be electrically connected to the first conductive pattern CPT1 through the first contact hole CH1. The second connection electrode CNE2 may be electrically connected to the second conductive pattern CPT2 through the second contact hole CH2.

The semiconductor pattern SP may overlap the first connection electrode CNE1, the second connection electrode CNE2, and the gate electrode GE. The semiconductor pattern SP may overlap the first conductive pattern CPT1 and the second conductive pattern CPT2. However, the present disclosure is not limited thereto, and the semiconductor pattern SP may have various shapes. For example, in one or more embodiments, the semiconductor pattern SP may not overlap the second conductive pattern CPT2.

The semiconductor pattern SP may include a semiconductor material such as poly silicon, crystalline silicon, and/or metal oxide. The semiconductor pattern SP may include the active region A-A, the source region S-A, and the drain region D-A. The semiconductor pattern SP may have different electrical property according to whether the semiconductor pattern SP is doped or not or whether metal oxide is reduced or not. The drain region D-A and the source region S-A of the semiconductor pattern SP having relatively high conductivity may serve as an electrode or a signal line. A region, of the semiconductor pattern SP, which is not doped or is doped at a low concentration, or is not reduced may correspond to the active region A-A having low conductivity. The active region A-A of the semiconductor pattern SP may be a portion of the semiconductor pattern SP overlapping the gate electrode GE. The active region A-A may have lower conductivity than the source region S-A and the drain region D-A.

A through hole may not be disposed in the semiconductor pattern SP of the transistor TR (see FIG. 4). The through hole may be formed in an etching process in which the first connection electrode CNE1, the second connection electrode CNE2, and the gate electrode GE are patterned.

However, the first conductive layer ML1 (see FIG. 4) according to the present disclosure may include a metal material that is dry etched, and the second conductive layer ML2 (see FIG. 4) may include a metal material that is wet etched, and thus a though hole may not be formed in an etching process in which the first connection electrode CNE1, the second connection electrode CNE2, and the gate electrode GE are patterned.

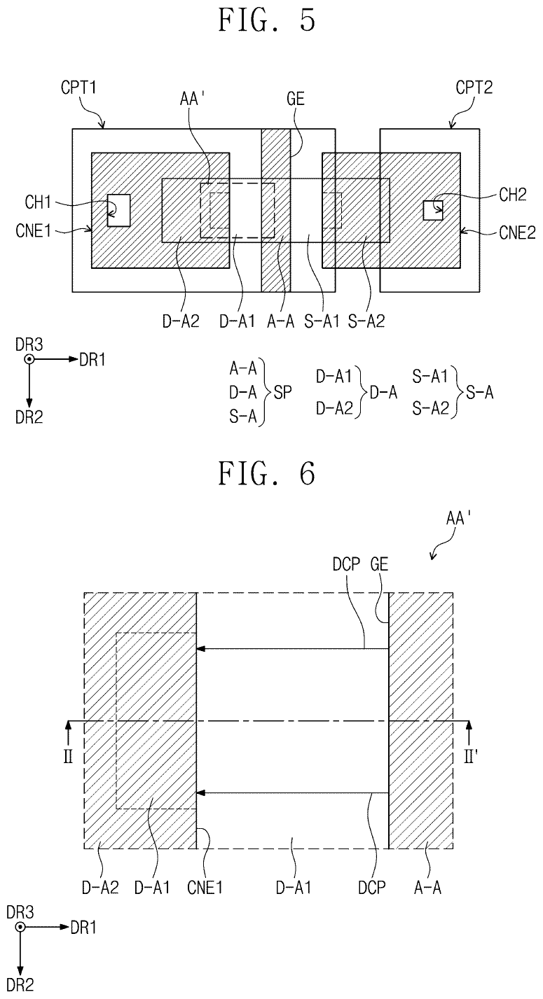

FIG. 6 is an enlarged plan view of a region AA′ of FIG. 5 according to one or more embodiments of the present disclosure.

Hereinafter, the same component as the component described above may be denoted by the same reference numerals or symbols, and detailed description thereof may not be provided. In addition, description of the drain region D-A with reference to FIG. 6 may be equally applied to the source region S-A (see FIG. 5).

Referring to FIG. 6, current flow DCP (e.g., also see FIG. 4) from the active region A-A may be immediately introduced into the first drain portion D-A1. According to one or more embodiments of the present disclosure, because no hole is defined in the semiconductor pattern SP, current is not introduced into the first drain portion D-A1 after avoiding a through hole unlike a case in which a through hole is defined in the semiconductor pattern SP.

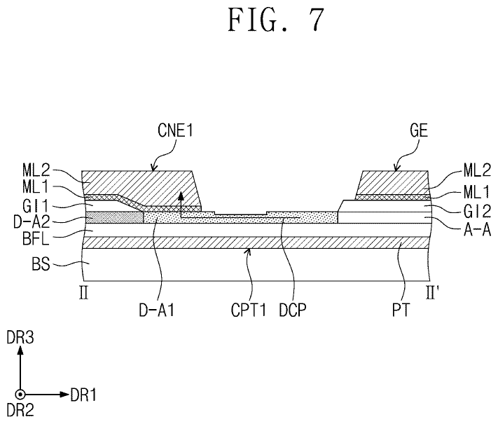

FIG. 7 is a cross-sectional view taken along the line II-II′ of FIG. 6 according to one or more embodiments of the present disclosure.

Hereinafter, the same component as the component described above will be denoted as the same reference numerals or symbols, and detailed description thereof will not be provided.

Referring to FIG. 7, the first gate insulating pattern Gi1 may cover the second drain portion D-A2. The first drain portion D-A1 may be directly in contact with and electrically connected to the first connection electrode CNE1. Because no through hole is defined in the semiconductor pattern SP (see FIG. 5), the current flow DCP from the active region A-A may immediately travel in an opposite direction of the first direction DR1 through the first drain portion D-A1. At a contact portion between the first drain portion D-A1 and the first connection electrode CNE1, the current flow DCP may move in the third direction DR3 and may be introduced into the first connection electrode CNE1.

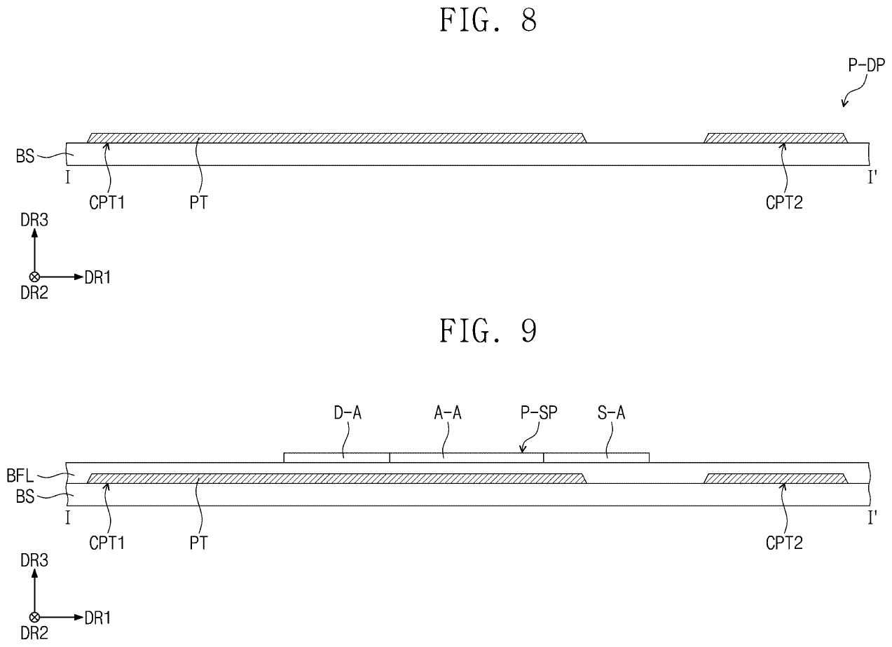

FIGS. 8-16 are cross-sectional views each illustrating a step of a manufacturing method of a display device according to one or more embodiments. FIGS. 8-16 each illustrate a cross-section taken along the line I-I′ of FIG. 3.

Hereinafter, the same component as the component described above will be denoted as the same reference numerals or symbols, and detailed description thereof will not be provided.

The manufacturing method of a display device according to one or more embodiments of the present disclosure may include providing a preliminary display panel P-DP, forming a semiconductor pattern SP, and forming a gate electrode GE.

FIG. 8 schematically illustrates the providing of the preliminary display panel P-DP. The preliminary display panel P-DP may include a base substrate BS and conductive patterns CPT1 and CPT2 disposed on the base substrate BS. The conductive patterns CPT1 and CPT2 may include a first conductive pattern CPT1 and a second conductive pattern CPT2 that are spaced (e.g., spaced apart) from the first conductive pattern CPT1 in a plan view. The first conductive pattern CPT1 and the second conductive pattern CPT2 may each be configured as a pattern layer PT.

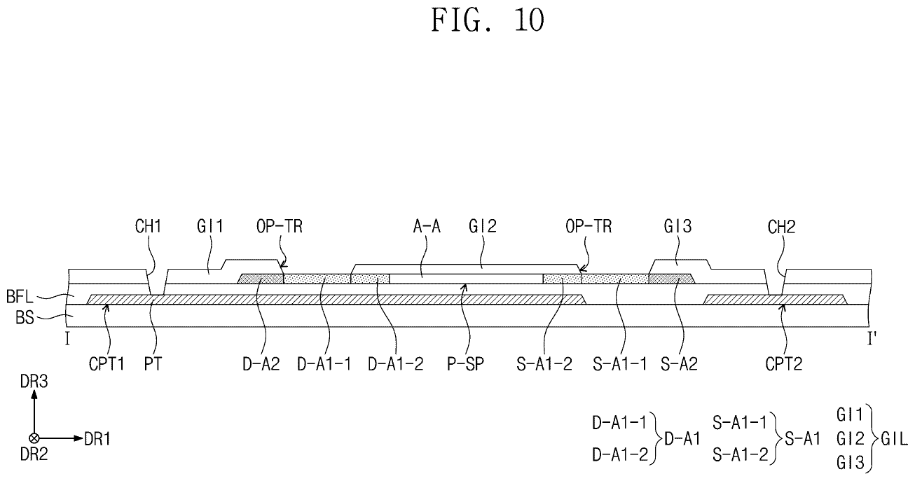

FIG. 9 schematically illustrates forming a buffer layer BFL and a preliminary semiconductor pattern P-SP. The buffer layer BFL may be formed covering the first conductive pattern CPT1 and the second conductive pattern CPT2. The preliminary semiconductor pattern P-SP may be formed on the buffer layer BFL. The preliminary semiconductor pattern P-SP may include a source region S-A, an active region A-A, and a drain region D-A.

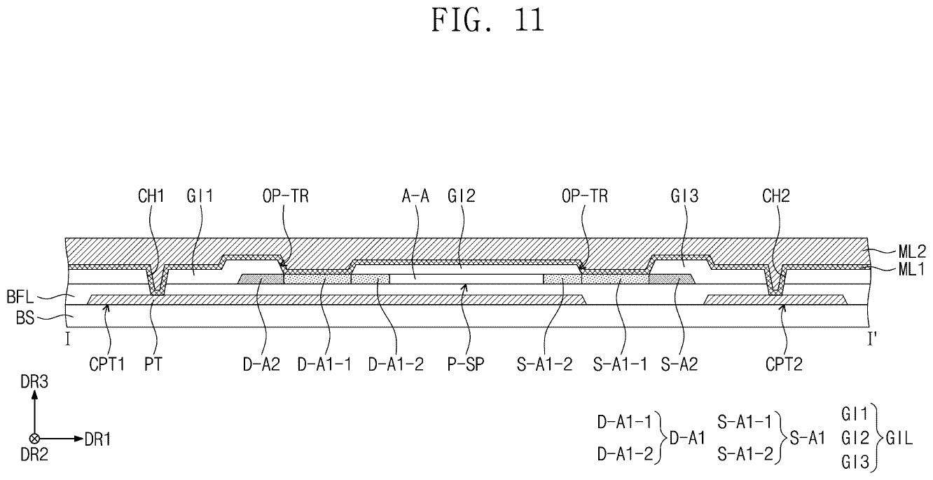

FIG. 10 schematically illustrates forming a gate insulating pattern layer GIL. The gate insulating pattern layer GIL may be formed on the preliminary semiconductor pattern P-SP. A first contact hole CH1 that exposes an upper surface of the first conductive pattern CPT1 may be formed in the gate insulating pattern layer GIL and the buffer layer BFL. A second contact hole CH2 that exposes an upper surface of the second conductive pattern CPT2 may be formed in the gate insulating pattern layer GIL and the buffer layer BFL. An insulating layer opening OP-TR that exposes a portion of the preliminary semiconductor pattern P-SP may be formed in the gate insulating pattern layer GIL. The gate insulating pattern layer GIL may include first to third insulating patterns G11, G12, and G13 that are spaced (e.g., spaced apart) from each other. The first gate insulating pattern G11 may cover a second drain portion D-A2. The second gate insulating pattern G12 may cover a (1-2)-th drain portion D-A1-2, the active region A-A, and a (1-2)-th source portion S-A1-2. The third gate insulating pattern G13 may cover a second source portion S-A2.

The first contact hole CH1, the second contact hole CH2, and the insulating layer opening OP-TR of the gate insulating pattern layer GIL may be formed through the same etching process.

When forming the insulating layer opening OP-TR, a first portion of the preliminary semiconductor pattern P-SP exposed by the insulating layer opening OP-TR may be doped. Here, exposed (1-1)-th drain portion D-A1-1 and (1-1)-th source portion S-A1-1 may be doped.

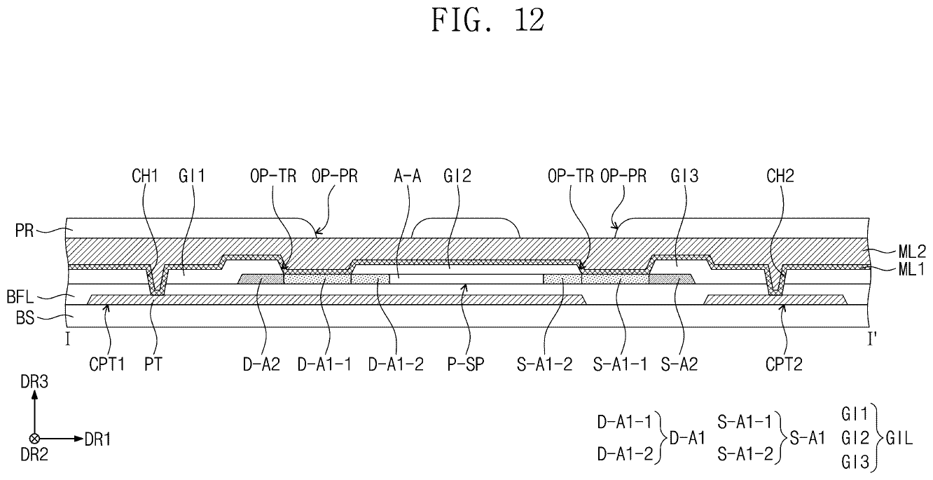

FIG. 11 schematically illustrates forming conductive layers ML1 and ML2. The conductive layers ML1 and ML2 may include a first conductive layer ML1 and a second conductive layer ML2. The conductive layers ML1 and ML2 may cover the preliminary semiconductor pattern P-SP. The conductive layers ML1 and ML2 may fill the first contact hole CH1, the second contact hole CH2, and the insulating layer opening OP-TR. Here, the first conductive layer ML1 may be directly in contact with the (1-1)-th drain portion D-A1-1 and the (1-1)-th source portion S-A1-1. The first conductive layer ML1 may include a material that may be dry etched. The first conductive layer ML1 may include a material that may be preserved without being etched by an etching solution capable of wet etching the second conductive layer ML2. For example, the first conductive layer ML1 may include titanium, molybdenum, or an alloy thereof. Accordingly, in etching the second conductive layer ML2 to be described later, the first conductive layer ML1 may not be etched, and the semiconductor pattern SP disposed under the first conductive layer ML1 may be protected by the first conductive layer ML1 and thus may not be damaged. The second conductive layer ML2 may include a material that may be wet etched. For example, the second conductive layer ML2 may include copper.

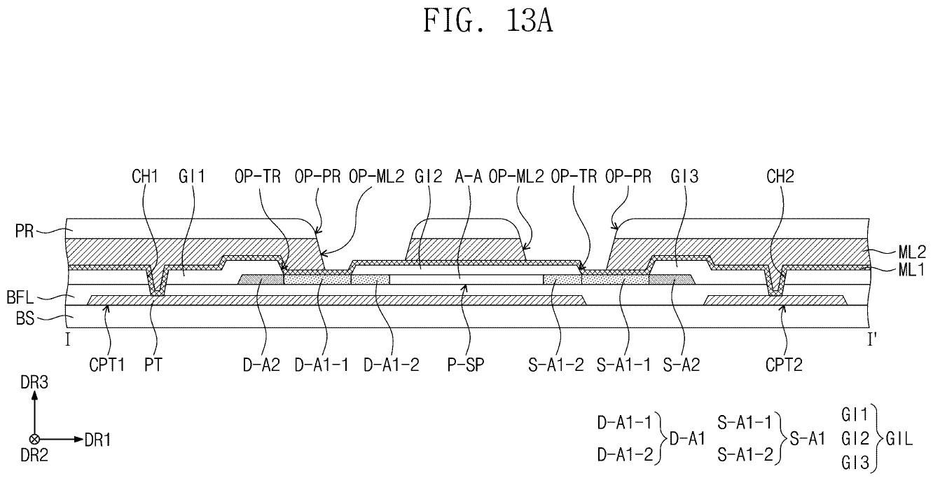

FIG. 12 schematically illustrates forming a photoresist layer PR. The photoresist layer PR having a photo opening OP-PR defined therein may be formed on the second conductive layer ML2. The photoresist layer PR may be formed to etch a portion corresponding to the photo opening OP-PR.

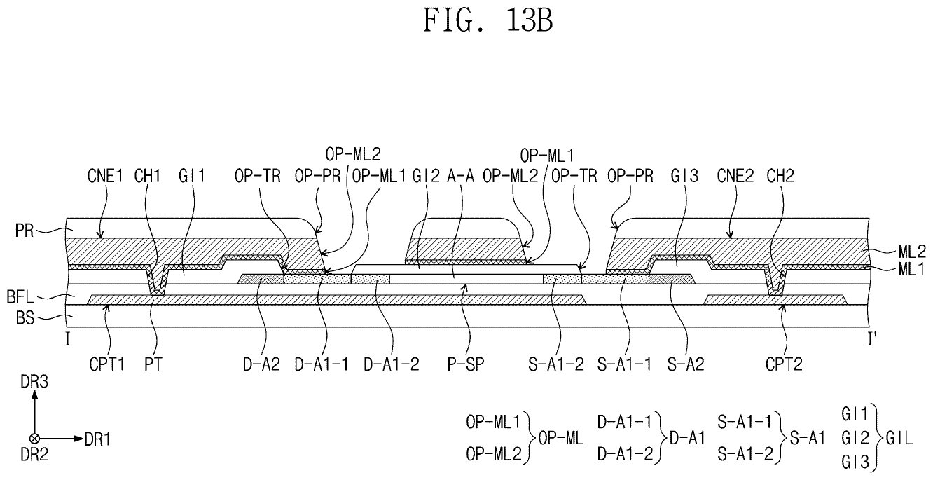

FIGS. 13A and 13B each schematically illustrate a step of patterning the gate electrode GE, a first connection electrode CNE1, and a second connection electrode CNE2. FIG. 13A illustrates etching the second conductive layer ML2. FIG. 13B illustrates etching the first conductive layer ML1.

Referring to FIG. 13A, a second conductive layer opening OP-ML2 corresponding to the photo opening OP-PR may be formed in the second conductive layer ML2. The second conductive layer opening OP-ML2 may expose a portion of the first conductive layer. The etching of the second conductive layer ML2 may include wet etching the second conductive layer ML2 corresponding to the photo opening OP-PR. The first conductive layer ML1 may be maintained without being etched by an etching solution that wet etches the second conductive layer ML2. Thus, the preliminary semiconductor pattern P-SP disposed under the first conductive layer ML1 may be protected without being damaged by the etching solution.

Referring to FIG. 13B, a first conductive layer opening OP-ML1 (e.g., also see FIG. 4) corresponding to the second conductive layer opening OP-ML2 may be formed in the first conductive layer ML1. The first conductive layer opening OP-ML1 may expose a portion of the preliminary semiconductor pattern P-SP. Specifically, the first conductive layer opening OP-ML1 may expose a portion of each of the (1-1)-th drain portion D-A1-1 and the (1-1)-th source portion S-A1-1. The etching of the first conductive layer ML1 may include dry etching the first conductive layer ML1 corresponding to the second conductive layer opening OP-ML2.

The first conductive layer opening OP-ML1 and the second conductive layer opening OP-ML2 may constitute a conductive layer opening OP-ML. The conductive layers ML1 and ML2 may be divided into the gate electrode GE, the first connection electrode CNE1, and the second connection electrode CNE2 by the conductive layer opening OP-ML.

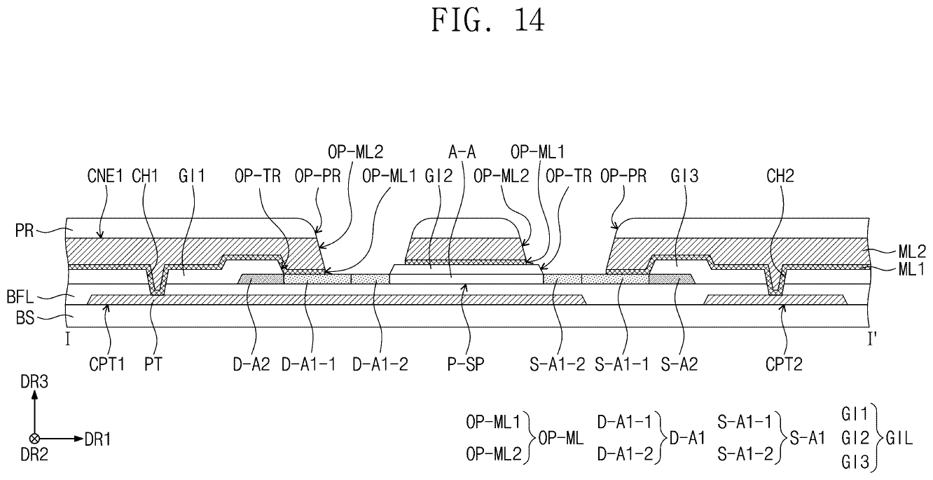

FIG. 14 schematically illustrates etching the gate insulating pattern layer GIL. A portion of the second gate insulating pattern G12 corresponding to the conductive layer opening OP-ML may be etched. The portion of the second gate insulating pattern G12 exposed by the conductive layer opening OP-ML may be etched through a dry etching process. Here, the (1-2)-th drain portion D-A1-2 and the (1-2)-th source portion S-A1-2 covered with the second gate insulating pattern G12 may be doped.

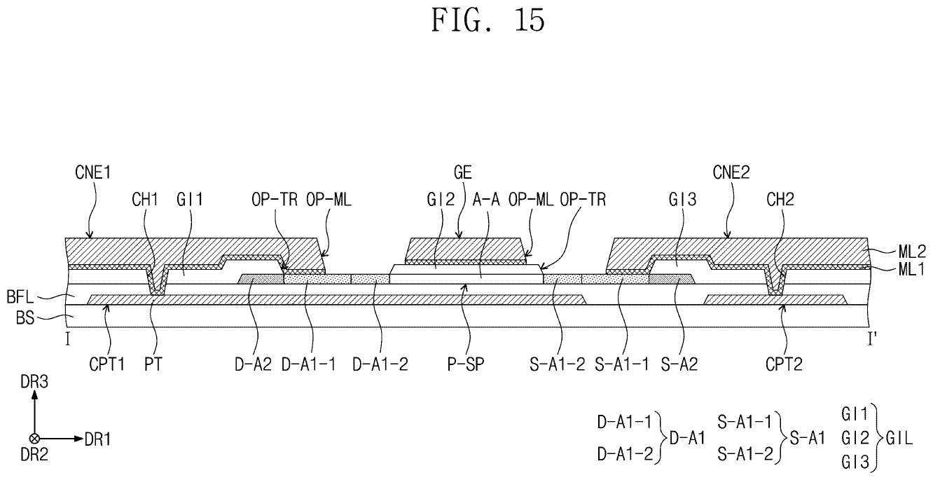

FIG. 15 schematically illustrates removing the photoresist layer PR. The photoresist layer PR, which serves as a mask, may be removed. An end of the first connection electrode CNE1 may be in contact with the (1-1)-th drain portion D-A1-1. An end of the second connection electrode CNE2 may be in contact with the (1-1)-th source portion S-A1-1.

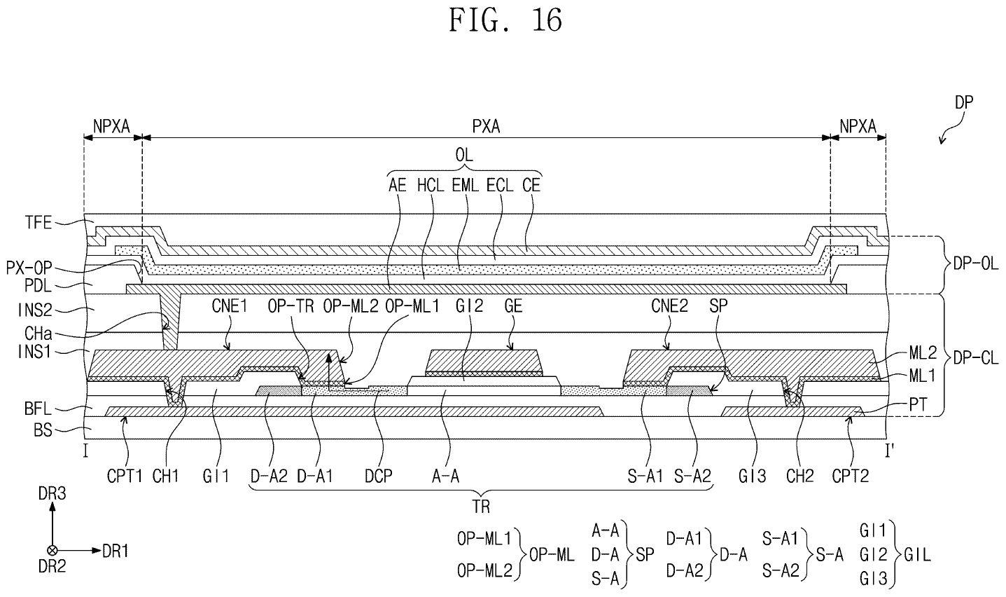

FIG. 16 schematically illustrates forming insulating layers INS1 and INS2, a display element layer DP-OL, and an encapsulation layer TFE, which is described above with reference to FIG. 4, and thus description thereof will not be provided.

In a manufacturing method of a display device according to the present disclosure, the conductive layers ML1 and ML2 for forming the gate electrode GE and the connection electrodes CNE1 and CNE2 are formed of materials having different etching characteristics. Because the second conductive layer ML2 may be patterned through wet etching with an etching solution with which the first conductive layer ML1 is not etched, the semiconductor pattern SP disposed under the first conductive layer ML1 may be protected, and damage such as causing a through hole may not occur.

Specifically, if the source region S-A and the drain region D-A of the semiconductor pattern SP are damaged and a through hole is formed therein, current flow may be disturbed and contact resistance may be increased, and thus element characteristics may be deteriorated. However, in the display device DD (see FIG. 1A), which is manufactured according to the manufacturing method of a display device according to the present disclosure, because the source region S-A and the drain region D-A of the semiconductor pattern SP may not be damaged, current flow may be smooth and contact resistance may be reduced, and thus element characteristics may be improved.

In a display device according to the present disclosure and a manufacturing method thereof, a gate electrode and a connection electrode may include two conductive layers having different etching characteristics, thereby preventing a semiconductor pattern disposed under the conductive layers from being damaged in a process of patterning the gate electrode and the connection electrode. Accordingly, current flow may be facilitated, and contact resistance may be reduced.

In addition, a mask process for a separate connection electrode may be skipped, and the connection electrode including the same material as the gate electrode may be used as a source and a drain, and thus a manufacturing process may be simplified, and a manufacturing cost may be reduced.

Although descriptions have been made with reference to the embodiments of the present disclosure, it is understood that the present disclosure should not be limited to these embodiments, but various changes and modifications may be made by one ordinary skilled in the art within the spirit and scope of the present disclosure as hereinafter claimed. Therefore, the technical scope of the present disclosure is not limited to the contents described in the detailed description of the specification, but should be determined by the accompanying claims and their equivalents.

What is claimed is:

1. A display device comprising:
a base substrate;
a transistor comprising a gate electrode and a semiconductor pattern, the semiconductor pattern including a source region, an active region, and a drain region and located on the base substrate;
a gate insulating pattern layer on the semiconductor pattern; and
a connection electrode electrically connected to the semiconductor pattern and being on the gate insulating pattern layer,
wherein the gate electrode and the connection electrode are at a same layer,
wherein each of the gate electrode and the connection electrode comprises a first conductive layer and a second conductive layer on the first conductive layer, and
wherein no through hole is defined in the semiconductor pattern.

2. The display device of claim 1, wherein the gate electrode and the connection electrode comprise a same material.

3. The display device of claim 1, wherein a thickness of the first conductive layer is smaller than a thickness of the second conductive layer.

4. The display device of claim 1, wherein the first conductive layer comprises a material that is not etched by an etching solution for etching the second conductive layer.

5. The display device of claim 1, wherein the first conductive layer comprises titanium (Ti), molybdenum (Mo), or an alloy thereof, and
wherein the second conductive layer comprises copper (Cu).

6. The display device of claim 1, wherein the connection electrode is electrically connected to the drain region or the source region.

7. The display device of claim 1, wherein the connection electrode comprises a first connection electrode directly in contact with and electrically connected to the drain region, and a second connection electrode directly in contact with and electrically connected to the source region.

8. The display device of claim 7, further comprising a first conductive pattern and a second conductive pattern between the base substrate and the transistor,
wherein the first conductive pattern is electrically connected to the drain region through the first connection electrode, and
wherein the second conductive pattern is electrically connected to the source region through the second connection electrode.

9. The display device of claim 1, further comprising a light-emitting element comprising a first electrode on the connection electrode, an emission layer on the first electrode, and a second electrode on the emission layer,
wherein the first electrode is electrically connected to the transistor through the connection electrode.

10. An electronic device comprising:
a display module;
a window on the display module; and
a housing under the display module;
wherein the display module comprises:
a base substrate;
a transistor comprising a gate electrode and a semiconductor pattern, the semiconductor pattern including a source region, an active region, and a drain region and located on the base substrate;
a gate insulating pattern layer on the semiconductor pattern; and
a connection electrode electrically connected to the semiconductor pattern and being on the gate insulating pattern layer,
wherein the gate electrode and the connection electrode are at a same layer,
wherein each of the gate electrode and the connection electrode comprises a first conductive layer comprising a first metal, and a second conductive layer comprising a second metal different from the first metal and located on the first conductive layer, and
wherein the second metal is not etched by an etching solution that etches the first metal.

11. The electronic device of claim 10, wherein the first conductive layer comprises titanium (Ti), molybdenum (Mo), or an alloy thereof, and
wherein the second conductive layer comprises copper (Cu).

12. The electronic device of claim 10, wherein a thickness of the first conductive layer is smaller than a thickness of the second conductive layer.

13. The electronic device of claim 10, wherein the gate electrode and the connection electrode comprise a same material.

14. The electronic device of claim 10, wherein no through hole is defined in the semiconductor pattern.

15. The electronic device of claim 10, wherein the connection electrode is electrically connected to the drain region or the source region.

16. The electronic device of claim 10, wherein the connection electrode comprises a first connection electrode directly in contact with and electrically connected to the drain region, and a second connection electrode directly in contact with and electrically connected to the source region.

17. The electronic device of claim 16, further comprising a first conductive pattern and a second conductive pattern between the base substrate and the transistor,
wherein the first conductive pattern is electrically connected to the drain region through the first connection electrode, and
wherein the second conductive pattern is electrically connected to the source region through the second connection electrode.

18. The electronic device of claim 10, further comprising a light-emitting element comprising a first electrode on the connection electrode, an emission layer on the first electrode, and a second electrode on the emission layer,
wherein the first electrode is electrically connected to the transistor through the connection electrode.

19. A manufacturing method of a display device, the manufacturing method comprising:
providing a preliminary display panel comprising a base substrate, a preliminary semiconductor pattern on the base substrate, and a gate insulating pattern layer having an insulating layer opening exposing a portion of the preliminary semiconductor pattern, the gate insulating pattern layer being on the preliminary semiconductor pattern;
forming a semiconductor pattern by doping a portion of the preliminary semiconductor pattern exposed by the insulating layer opening; and
forming a gate electrode and a connection electrode on the gate insulating pattern layer,
wherein the forming of the gate electrode and the connection electrode comprises:
forming a first conductive layer on the gate insulating pattern layer and forming a second conductive layer on the first conductive layer;
patterning the second conductive layer through wet etching; and
patterning the first conductive layer through dry etching.

20. The manufacturing method of claim 19, wherein in the patterning of the second conductive layer through wet etching, the semiconductor pattern is covered with the first conductive layer and prevented from being damaged.
